(19) United States
(12) Patent Application Publication
(10) Pub. No.: US 2005/0077594 A1
(43) Pub. Date: Apr. 14, 2005

(54) Semiconductor device with polysilicon fuse and method for trimming the same

(75) Inventors: Tomohiro Matsunaga, Osaka (JP); Hiroshi Mogami, Kanagawa (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/958,286

(22) Filed: Oct. 6, 2004

(30) Foreign Application Priority Data
Oct. 10, 2003 (JP) 2003-352017

(51) Int. Cl. H01L 23/62

(52) U.S. Cl. 257/529

(57) ABSTRACT

A semiconductor device includes a polysilicon fuse with a fusion portion and has a sequential stack made of an interlayer insulating film having a recess above the fusion portion, a surface passivation film having an opening on the recess, a buffer film filling the recess and the opening, and a sealing resin layer. The buffer film releases film stress on the polysilicon fuse placed by the sealing resin layer, and avoids influences of the film stress on trimming of the device. In a method for trimming a semiconductor device, trimming is carried out by applying to the polysilicon fuse a voltage pulse capable of melting the polysilicon fuse at the fusion portion and interrupting the applied voltage with a current flowing through the fuse. This avoids influences of film stress placed by the sealing resin.

### CROSS-REFERENCE TO RELATED APPLICATIONS

This application claims priority under 35 U.S.C. § 119 on Patent Application No. 2003-352017 filed in Japan on Oct. 10, 2003, the entire contents of which are hereby incorporated by reference.

### BACKGROUND OF THE INVENTION

(a) Fields of the Invention

The present invention relates to semiconductor devices with polysilicon fuses and methods for trimming such a device.

(b) Description of Related Art

Polysilicon fuses are utilized in various fields such as adjustment of the reference voltage of a circuit and data writing in a PROM (Programmable Read Only Memory).

FIGS. 6A and 6B are views for illustrating the structure of a conventional semiconductor device with a polysilicon fuse.

FIG. 6A is a view showing a plan configuration of the polysilicon fuse included in the semiconductor device. FIG. 6A shows as a see-through view a polysilicon fuse 11 having a fusion portion 11a, a lead-in wire 12 for applying a voltage to the polysilicon fuse 11, and a contact 13 connecting the polysilicon fuse 11 to the lead-in wire 12. The reference numeral 17a (16a) will be described in a later description of FIG. 6B. Other components are omitted in FIG. 6A.

FIG. 6B is a sectional view showing the conventional semiconductor device with the polysilicon fuse, and corresponds to a cross section taken along the line VIb-VIb′ in FIG. 6A.

Referring to FIG. 6B, the conventional semiconductor device with the polysilicon fuse includes a semiconductor substrate 14, a thermal oxide film 15 formed on the semiconductor substrate 14, the polysilicon fuse 11 formed on the thermal oxide film 15 and having the fusion portion 11a, the lead-in wire 12 for applying a voltage to the polysilicon fuse 11, and the contact 13 connecting the polysilicon fuse 11 to the lead-in wire 12. Over the thermal oxide film 15, an interlayer insulating film 16 is formed which covers the polysilicon fuse 11, the lead-in wire 12, and the contact 13 and has a recess 16a provided above the fusion portion 11a. On the interlayer insulating film 16, a surface passivation film 17 is formed which has an opening 17a on the recess 16a. In addition, a sealing resin layer 18 is formed on the surface passivation film 17.

As shown by the reference numeral 17a (16a) in FIG. 6A, the opening 17a is formed to superpose on the recess 16a. The sealing resin layer 18 fills the recess 16a and the opening 17a.

In this structure, provision of the recess 16a and the opening 17a releases film stress on the polysilicon fuse 11 or other portions placed by the sealing resin layer 18.

Next description will be made of a method for trimming the above-mentioned conventional semiconductor device with the polysilicon fuse 11, in other words, a method for performing writing in the conventional semiconductor device by applying a voltage to the polysilicon fuse 11 to blow the fuse at the fusion portion 11a.

Trimming of the semiconductor device is carried out by applying a predetermined voltage pulse to the polysilicon fuse 11 through the lead-in wire 12. FIG. 7 shows conventional writing waveforms (waveforms of applied voltage and current) for use in blowing the polysilicon fuse.

First, when a predetermined voltage pulse is applied to the polysilicon fuse 11, the value of a current flowing through the polysilicon fuse 11 increases with the increase in voltage. Then, generated Joule heat raises the temperature of the inside of the polysilicon fuse 11. In particular, since the fusion portion 11a has a smaller width than the other portions of the polysilicon fuse 11, it has a higher current density than the other portions. Therefore, it generates a large amount of heat.

As a result of this, when the temperature of the fusion portion 11a reaches 1410° C., which is a melting point of silicon, the fusion portion 11a begins to melt. Then, the inside of the fusion portion 11a is formed with a structure called filament in which part of polysilicon is melted into liquid.

Once the filament is created, the current sharply rises due to a high conductivity of molten polysilicon. Thus, the filament grows widthwise and thicknesswise within the fusion portion 11a, and finally splits and blows by actions of surface tension of the liquefied polysilicon itself and of film stress on the polysilicon fuse 11 placed by the sealing resin layer 18. In the manner described above, the polysilicon fuse 11 is blown at the fusion portion 11a.

The voltage pulse applied in thus blowing the polysilicon fuse 11 still continues to apply a voltage even after the filament is created and a large amount of current sharply flows and until the filament splits to let the flowing current reach completely zero. To be more specific, for example, the voltage pulse has a pulse width from 1 to 2 msec inclusive.

Note that documents known as prior art references relating to the invention of this patent application are, for example, Japanese Unexamined Patent Publication No. H11-163144 as a patent document, A. Ito, E. W. (Pete) George, R. K. Lowry, H. A. Swasey, and other four people, “The Physics and Reliability of Fusing Polysilicon” (IEEE IRPS (1984) Vol. 17) as a non-patent document, and Alan Hastings, “The Art of Analog Layout” (pp. 185 to 189) as another non-patent document.

### SUMMARY OF THE INVENTION

The conventional semiconductor device with the polysilicon fuse and the conventional trimming method of the device that are mentioned above, however, have problems described below.

Film stress on the polysilicon fuse 11 placed by the sealing resin layer 18 differs depending on the type and the coating condition of sealing resin. This sometimes hinders or otherwise promotes the blowout of the polysilicon fuse 11, and in addition the extent of the hindrance or promotion varies greatly. Accordingly, it is difficult to control the blowout of the polysilicon fuse 11.

Particularly, in the conventional structure of the device, the sealing resin layer 18 is formed immediately above the surface passivation film 17, and the recess 16a and the opening 17a are filled with the sealing resin layer 18. Because of such a structure, film stress by the sealing resin layer 18 has a large impact on the blowout of the polysilicon fuse 11.

If the film stress on the polysilicon fuse 11 placed by the sealing resin layer 18 acts as hindrance to the blowout of the fusion portion 11a, an inadequate blowout, a long-time blowout, or other influences arise. This makes it impossible to carry out a stable blowout. In particular, if it takes a long period of time for the blowout, Joule heat also continues to be generated for a long time. This causes damages such as melting and breakage of the thermal oxide film 15, the interlayer insulating film 16, and other portions in contact with the heat-generating polysilicon fuse 11. Moreover, the heat generated in the polysilicon fuse 11 may be transferred through the surface passivation film 17 to the sealing resin layer 18, through the thermal oxide film 15 to the semiconductor substrate 14, or through the contact 13 to the lead-in wire 12, thereby causing melting or other damages to the semiconductor device. In the writing waveforms shown in FIG. 7, the current sharply increases once (the current is beyond the illustrated range) after the fuse is blown and before the current value reaches zero. This probably indicates the occurrence of damages by the melting as described above.

If the sealing resin layer 18 having a great film stress on the polysilicon fuse 11 (that is, a hard sealing resin layer 18) is employed in this device, the film stress may act as hindrance to the blowout, thereby taking a long period of time (for example, about 30 μsec) for a complete blowout. In this case, the amount of generated Joule heat increases to provide an excessive blowout of the fusion portion 11a of the polysilicon fuse and to cause damages to the semiconductor device as described above.

In addition, in the conventional trimming method of a semiconductor device, after the filament is created and a large amount of current begins to flow, a voltage still continues to be applied until the current reaches completely zero. This means that a voltage continues to be applied until the liquefied polysilicon is split by the actions of surface tension of the liquefied polysilicon and of film stress on the polysilicon fuse 11 placed by the sealing resin layer 18. Therefore, in the case where polysilicon is not split in a short time due to influences of the film stress on the polysilicon fuse 11, a problem arises that influences of the heat generated in the polysilicon fuse 11 increase to cause damages to the semiconductor device as described above.

The present invention has been made to solve the problems described above, and an object thereof is to provide a semiconductor device having a built-in a polysilicon fuse which can conduct a stable writing (blowout of the polysilicon fuse) without suffering influences of film stress on the polysilicon fuse placed by a sealing resin layer, and to provide a trimming method of such a device.

To attain the above object, a first semiconductor device of the present invention comprises: a polysilicon fuse with a fusion portion; an interlayer insulating film formed to cover the polysilicon fuse and having a recess above the fusion portion; a surface passivation film formed on the interlayer insulating film and having an opening on the recess; a buffer film formed on the surface passivation film and filling the recess and the opening; and a sealing resin layer formed on the buffer film. The buffer film releases film stress on the polysilicon fuse placed by the sealing resin layer.

In the first semiconductor device, the buffer film is formed between the surface passivation film and the sealing resin layer. This releases film stress on the polysilicon fuse placed by the sealing resin layer (referred hereinafter to as film stress by the sealing resin layer).

In the first semiconductor device, by appropriately selecting a material for and a formation method of the buffer film, film stress on the polysilicon fuse placed by the buffer film (referred hereinafter to as film stress by the buffer film) is designed to be smaller than the film stress by the sealing resin layer of the semiconductor device formed with no buffer film (that is, the sealing resin layer formed directly above the surface passivation film). Note that in this description, the film stress may be either of compressive stress and tensile stress and comparison is made using the absolute value of the stress.

With the first semiconductor device thus designed, the buffer film can be formed to reduce total film stress on the polysilicon fuse placed by components of the semiconductor device such as the sealing resin, the buffer film, and the interlayer insulating film.

As a result of the above, in the first semiconductor device, the buffer film releases film stress placed on the polysilicon fuse, whereby a stable trimming can be carried out.

A second semiconductor device of the present invention comprises: a polysilicon fuse with a fusion portion; an interlayer insulating film formed to cover the polysilicon fuse and having a recess above the fusion portion; a buffer film formed on the interlayer insulating film and filling the recess; and a sealing resin layer formed on the buffer film. The buffer film releases film stress on the polysilicon fuse placed by the sealing resin layer.

The second semiconductor device can exert the same effects as the first semiconductor device. Moreover, the buffer film functions also as a surface passivation film, so that formation of the surface passivation film can be eliminated. Therefore, the structure and the fabrication method of the semiconductor device can be simplified.

Preferably, the buffer film is made of an organic insulating film.

With the second semiconductor device thus designed, the buffer film capable of releasing film stress placed by the sealing resin layer can be formed with reliability. Therefore, the effects of the semiconductor device of the present invention can be exerted certainly.

Preferably, the organic insulating film is a polyimide film.

With the second semiconductor device thus designed, the organic insulating film capable of releasing film stress placed by the sealing resin layer can be formed with reliability. Therefore, the effects of the semiconductor device of the present invention can be exerted more certainly.

To attain the above object, in a method for trimming a semiconductor device of the present invention, the semiconductor device comprises a polysilicon fuse with a fusion portion, and trimming is carried out by: applying a voltage to the polysilicon fuse to melt the fusion portion; and stopping, a predetermined time later after the start of the voltage application, the voltage application with a current flowing through the molten polysilicon fuse.

With this method, a voltage is applied to melt the polysilicon fuse into liquid and simultaneously to melt the interlayer insulating film and the like adjacent to the polysilicon fuse. By oxygen contained in the interlayer insulating film and the like, the melted polysilicon fuse is oxidized into oxide. Thereafter, when the voltage application is stopped with a current flowing through the molten polysilicon fuse in the form of oxide, generation of Joule heat is stopped. This rapidly cools and solidifies the molten oxide to finally produce an insulator of oxide. As a result, the polysilicon fuse is electrically insulated, and thus trimming of the semiconductor device can be accomplished.

It is unnecessary for the trimming method described above to split a filament formed of the molten polysilicon fuse. This avoids influences of the film stress on the polysilicon fuse placed by the sealing resin layer and the like, and provides a stable trimming. Moreover, the period of time for which Joule heat continues to be generated is shorter than that of the conventional trimming method in which the voltage application is continued until the filament splits to stop the current flow. Therefore, damages of the generated heat to the semiconductor device can be reduced.

Preferably, the predetermined time for which a voltage is applied is from 3 to 100 μsec inclusive.

This ensures oxidation of the molten fusion portion of the polysilicon fuse, so that a reliable writing can be carried out. Moreover, since the period of time for which Joule heat continues to be generated in the fusion portion is sufficiently short, damages to the semiconductor device can be reduced certainly.

More preferably, the predetermined time for which a voltage is applied is from 3 to 10 μsec inclusive.

This ensures oxidation of the molten fusion portion of the polysilicon fuse, so that a reliable writing can be carried out. Moreover, since the period of time for which Joule heat continues to be generated in the fusion portion is sufficiently short, damages to the semiconductor device can be reduced more certainly.

Preferably, in the method for trimming a semiconductor device of the present invention, the semiconductor device comprises: a polysilicon fuse formed above a semiconductor substrate and having a fusion portion; an interlayer insulating film formed over the semiconductor substrate so that the interlayer insulating film covers the polysilicon fuse and having a recess above the fusion portion; a buffer film formed on the interlayer insulating film and filling the recess; and a sealing resin layer formed on the buffer film. The buffer film preferably releases film stress on the polysilicon fuse placed by the sealing resin layer.

With this method, the semiconductor device having the structure in which the buffer film releases film stress placed by the sealing resin layer can obtain the effects of the inventive trimming method in which trimming is carried out by stopping the voltage application with a current flowing through the molten polysilicon fuse.

As described above, in the semiconductor device of the present invention, the buffer film is formed between the sealing resin layer and the polysilicon fuse. This reduces film stress on the polysilicon fuse. Therefore, a stable blowout of the polysilicon fuse in the resin-sealed semiconductor device can be carried out.

Furthermore, with the method for trimming a semiconductor device of the present invention, the polysilicon fuse can be electrically insulated without the need for splitting the filament formed of the molten polysilicon fuse. Therefore, even in the case where the polysilicon fuse receives a large film stress, a stable trimming can be carried out. In addition, since the period of voltage application is short, damages to the semiconductor device can be reduced.

Accordingly, the semiconductor device with the polysilicon fuse and the trimming method thereof according to the present invention are useful for semiconductor devices and the like for communications tools or audiovisual tools, which are requested to have high-quality electrical properties.

### BRIEF DESCRIPTION OF THE DRAWINGS

FIGS. 1A and 1B are views each showing the structure of a semiconductor device with a polysilicon fuse according to a first embodiment of the present invention. FIG. 1A is a see-through plan view showing only some components thereof, and FIG. 1B is a sectional view taken along the line Ib-Ib′ in FIG. 1A.

FIG. 2A is a graph showing writing waveforms for use in trimming the semiconductor device according to the first embodiment of the present invention, and FIG. 2B is an enlarged graph showing part of the graph of FIG. 2A.

FIGS. 3A and 3B are views each showing the structure of a semiconductor device with a polysilicon fuse according to a modification of the first embodiment of the present invention. FIG. 3A is a see-through plan view showing only some components thereof, and FIG. 3B is a sectional view taken along the line IIIb-IIIb′ in FIG. 3A.

FIG. 4A is a graph showing writing waveforms in a method for trimming a semiconductor device according to a second embodiment of the present invention, and FIG. 4B is an enlarged graph showing part of the graph of FIG. 4A.

FIG. 5 is a graph showing the pulse period dependence of the writing yield in the method for trimming a semiconductor device according to the second embodiment of the present invention.

FIGS. 6A and 6B are views each showing the structure of a conventional semiconductor device with a polysilicon fuse. FIG. 6A is a see-through plan view showing only some components thereof, and FIG. 6B is a sectional view taken along the line VIb-VIb′ in FIG. 6A.

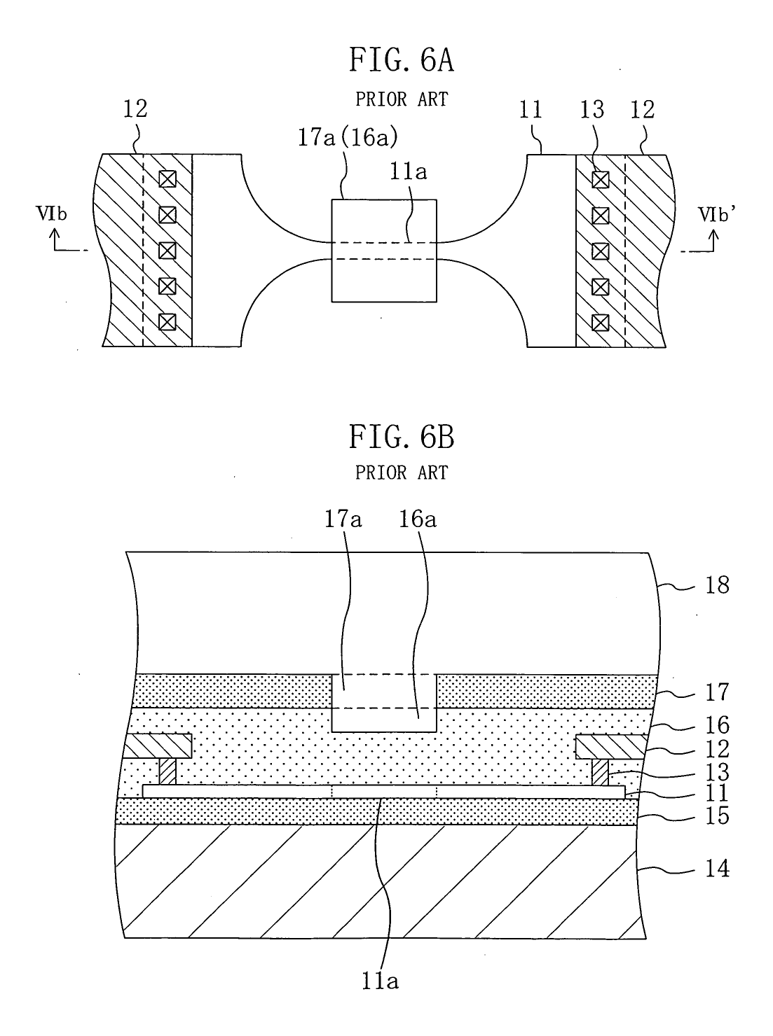

FIG. 7 is a graph showing writing waveforms for use in trimming the conventional semiconductor device.

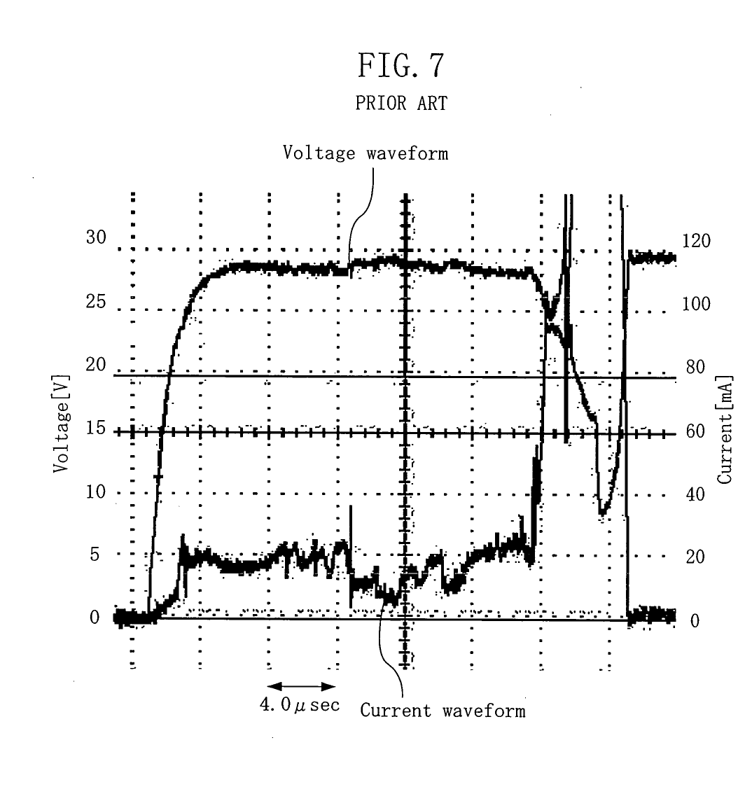

### DETAILED DESCRIPTION OF THE PREFERRED EMBODIMENTS

### First Embodiment

A first embodiment of the present invention will be described below with reference to the accompanying drawings.

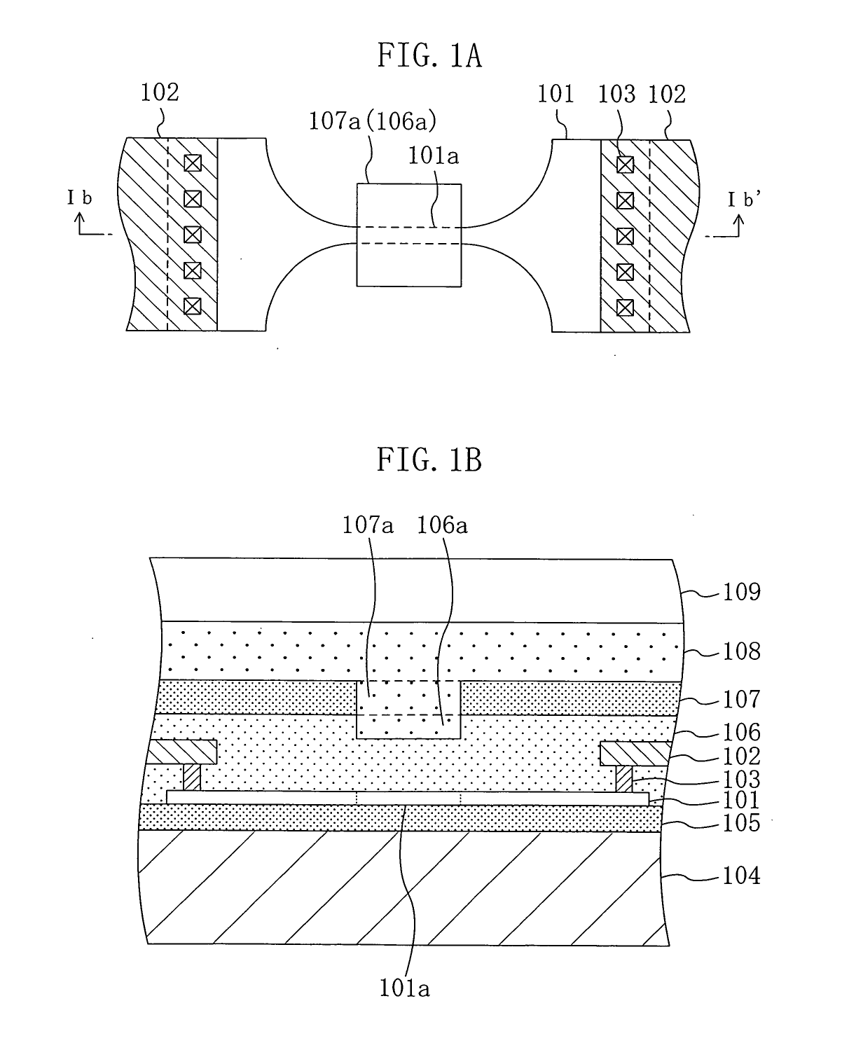

FIGS. 1A and 1B are views for illustrating the structure of a semiconductor device with a polysilicon fuse according to the first embodiment.

FIG. 1A is a view showing a plan configuration of the polysilicon fuse included in the semiconductor device of the first embodiment. FIG. 1A shows as a see-through view a polysilicon fuse 101 having a fusion portion 101a, a lead-in wire 102 for applying a voltage to the polysilicon fuse 101, and a contact 103 connecting the polysilicon fuse 101 to the lead-in wire 102. The reference numeral 107a (106a) will be described in a later description of FIG. 1B. Illustration of other components is omitted in FIG. 1A.

FIG. 1B is a sectional view showing the semiconductor device with the polysilicon fuse according to the first embodiment, and corresponds to a cross section taken along the line Ib-Ib′ in FIG. 1A.

Referring to FIG. 1B, the semiconductor device with the polysilicon fuse according to this embodiment includes a semiconductor substrate 104, a thermal oxide film 105 formed on the semiconductor substrate 104, the polysilicon fuse 101 formed on the thermal oxide film 105 and having the fusion portion 101a, the lead-in wire 102 for applying a voltage to the polysilicon fuse 101, and the contact 103 connecting the polysilicon fuse 101 to the lead-in wire 102. Over the thermal oxide film 105, an interlayer insulating film 106 is formed which covers the polysilicon fuse 101, the lead-in wire 102, and the contact 103 and has a recess 106a provided above the fusion portion 101a. On the interlayer insulating film 106, a surface passivation film 107 is formed which has an opening 107a on the recess 106a. In addition, a buffer film 108 is formed on the surface passivation film 107, and a sealing resin layer 109 is formed on the buffer film 108.

As shown by the reference numeral 107a (106a) in FIG. 1A, the opening 107a is formed to superpose on the recess 106a. The buffer film 108 fills the recess 106a and the opening 107a.

The interlayer insulating film 106 is formed of SiO₂ or the like, the surface passivation film 107 is formed of SiN or the like, the buffer film 108 is formed of polyimide or the like, and the sealing resin layer 109 is formed of phenolic resin or the like. However, the materials for the respective components are not limited to these. In addition, instead of the thermal oxide film 105, another type of insulating film can also be employed thereas.

A characteristic of the semiconductor device of the first embodiment is that the buffer film 108 is formed between the surface passivation film 107 and the sealing resin layer 109 and fills the recess 106a and the opening 107a.

The buffer film 108 releases film stress on the polysilicon fuse 101 placed by the sealing resin layer 109 of phenolic resin or the like (referred hereinafter to as film stress by the sealing resin layer 109). Moreover, film stress on the polysilicon fuse 101 placed by the buffer film 108 (referred hereinafter to as film stress by the buffer film 108) is designed to be smaller than film stress by the sealing resin layer 109 included in the semiconductor device of the conventional structure formed with no buffer film 108.

As is apparent from the above, since the film stress on the polysilicon fuse 101 is released, a stable blowout of the polysilicon fuse 101 can be carried out at the fusion portion 101a.

By forming the buffer film 108 of polyimide or the like exhibiting an insulating property, the buffer film 108 can also function as an insulating film.

Trimming of the semiconductor device of the first embodiment is carried out in the manner described below.

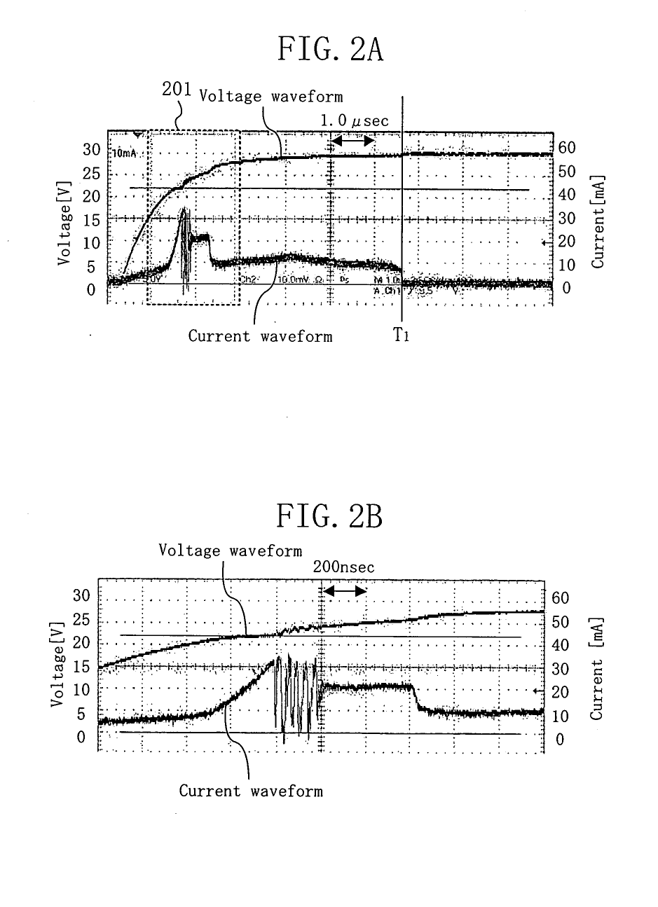

FIG. 2A is a graph showing exemplary writing waveforms (voltage pulse) for trimming the semiconductor device of the first embodiment, of which waveform portions 201 surrounded with the broken lines are enlargedly shown in FIG. 2B.

When a voltage pulse as shown in FIG. 2A is applied to the polysilicon fuse 101 included in the semiconductor device of the first embodiment shown in FIGS. 1A and 1B, the value of a current flowing through the polysilicon fuse 101 increases with the increase in voltage. Then, generated Joule heat raises the temperature of the inside of the polysilicon fuse 101. In particular, since the fusion portion 101a has a smaller width than the other portions of the polysilicon fuse 101, it has a higher current density than the other portions. Therefore, it generates a large amount of heat.

As a result of this, when the temperature of the polysilicon fuse 101 reaches 1410° C. which is a melting point of silicon, it begins to melt at part of the fusion portion 101a, thereby creating a liquefied filament. Once the filament is created in the fuse, the current flowing therethrough sharply rises due to a high conductivity of molten polysilicon. Further, the filament grows widthwise and thicknesswise within the fusion portion 101a, and finally splits by the actions of surface tension of liquefied polysilicon itself and of film stress placed by the buffer film 108 and the sealing resin layer 109, resulting in blowout of the polysilicon fuse 101. In FIG. 2A, the time T₁ the current has reached zero indicates the time the blowout has occurred.

In this trimming, as described previously, the presence of the buffer film 108 releases total film stress placed on the polysilicon fuse 101. This enables a stable blowout of the polysilicon fuse 101 (trimming of the semiconductor device).

In the semiconductor device of the first embodiment, a polyimide film is employed as the buffer film 108. However, the material for the buffer film 108 is not limited to this, and a material capable of releasing the film stress placed by the sealing resin layer 109 can be used thereas. For example, it is acceptable to use a material capable of forming the buffer film 108 with a smaller film stress on the polysilicon fuse 101 than film stress by the sealing resin layer 109 of the semiconductor device formed with no buffer film 108. Specifically, for example, an organic polymer film such as an aromatic ether film or an organic insulating film such as an organic SOG (spin on glass) film may be used thereas. An inorganic insulating film such as a silicon oxide film formed by atmospheric CVD (chemical vapor deposition) or the like can also be used instead.

### Modification of First Embodiment

Next, a modification of the first embodiment will be described with reference to the accompanying drawings.

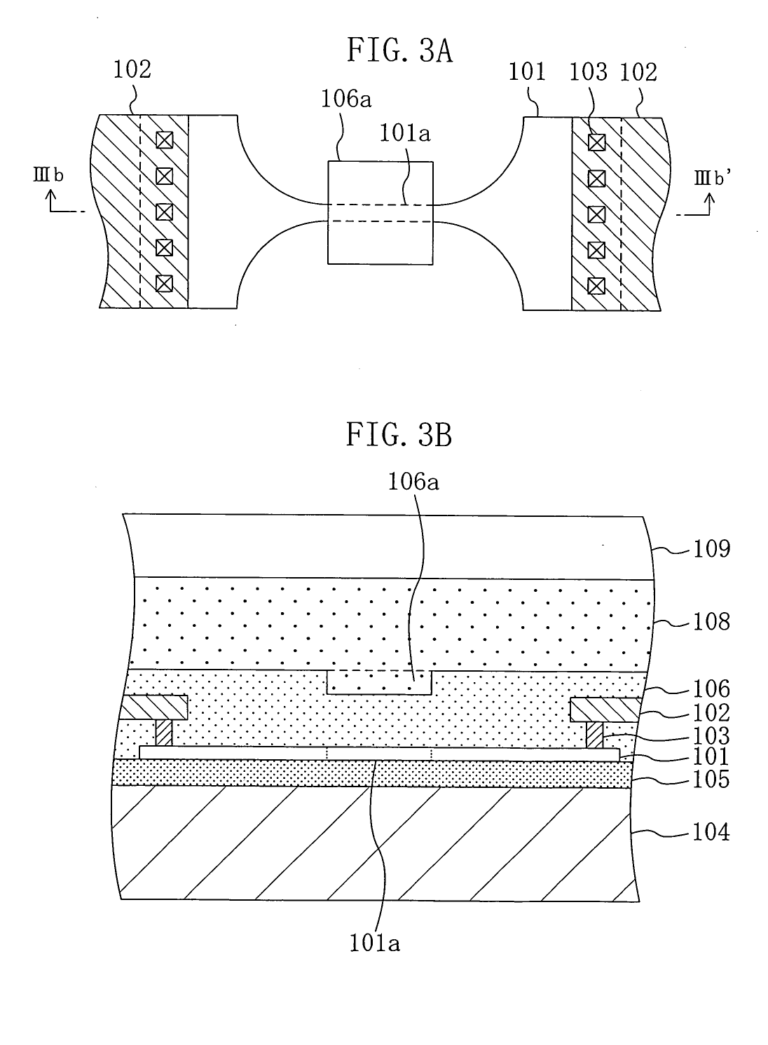

FIGS. 3A and 3B each show the structure of a semiconductor device with a polysilicon fuse according to this modification.

FIG. 3A is a view showing a plan configuration of the polysilicon fuse included in the semiconductor device according to this modification. Herein, detail description of the components shown in the plan configuration of FIG. 3A that are the same as those shown in the plan configuration of FIG. 1A will be omitted by retaining the same reference numerals. The plan configurations shown in FIGS. 1A and 3A differ in that the reference numeral 107a is not illustrated in FIG. 3A because the surface passivation film 107 and the opening 107a are not formed in this modification.

FIG. 3B is a sectional view showing the semiconductor device with the polysilicon fuse according to this modification, and corresponds to a cross section taken along the line IIIb-IIIb′ in FIG. 3A. The difference between the semiconductor device of this modification shown in FIG. 3B and the semiconductor device of the first embodiment is that the buffer film 108 functions also as the surface passivation film 107 to eliminate the surface passivation film 107. As a matter of course, no opening 107a is formed in this modification. Other components shown in FIG. 3B are the same as those shown in FIG. 1B, so that detail description thereof will be omitted by retaining the same reference numerals as those in FIG. 1B.

The modification of the first embodiment can exert the same effects as the first embodiment. Moreover, since the surface passivation film 107 is eliminated, the structure and the fabrication method of the semiconductor device can be simplified.

### Second Embodiment

Next, a trimming method of (writing method in) a semiconductor device according to a second embodiment will be described with reference to the accompanying drawings.

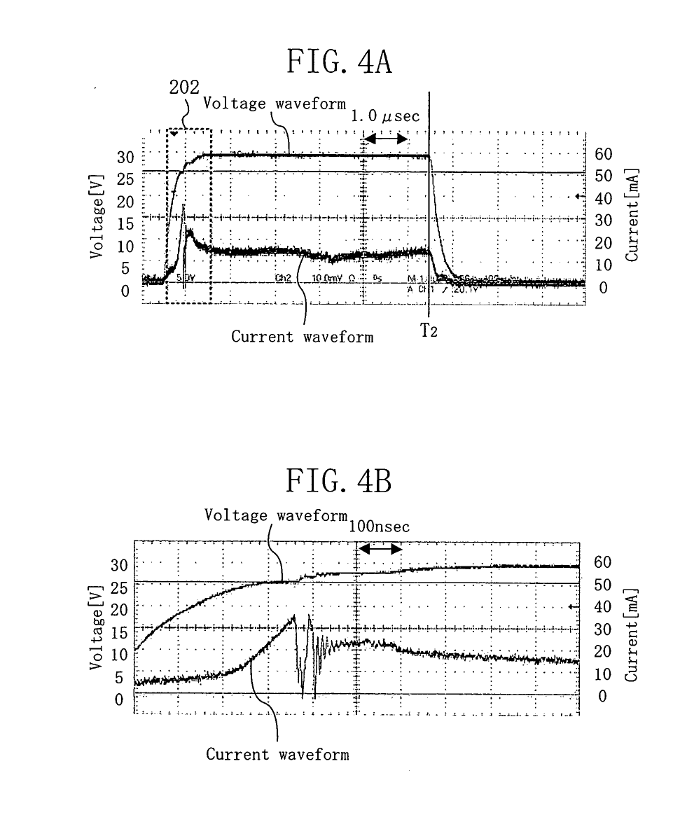

In this embodiment, trimming of the semiconductor device according to the first embodiment is carried out. FIG. 4A shows exemplary writing waveforms used in this embodiment, of which waveform portions 202 surrounded with the broken lines are enlargedly shown in FIG. 4B.

Like the trimming method of the semiconductor device of the first embodiment, application of a voltage pulse to the polysilicon fuse 101 makes a current flow through the polysilicon fuse 101, and then Joule heat is generated therein. This creates a filament and the current flowing sharply rises. Simultaneously, the created filament grows widthwise and thicknesswise within the fusion portion 101a. The foregoing process is similar to that of the first embodiment.

In the first embodiment, after the current rise, a voltage still continues to be applied for about 1 to 2 msec. Finally, the filament splits by the actions of surface tension of liquefied polysilicon itself and of film stress by the buffer film 108, the sealing resin layer 109, and the like, resulting in blowout of the polysilicon fuse 101. The time the blowout has occurred is indicated by the time T₁ the current has reached zero in FIG. 2A.

In contrast to this, in the second embodiment, trimming of the semiconductor device is carried out by making an applied voltage zero before the filament splits. This will now be described below.

As previously mentioned, the filament created by the voltage application to the polysilicon fuse 101 grows within the polysilicon fuse 101. During this growth, heat transfers also to the thermal oxide film 105 and the interlayer insulating film 106 adjacent to the polysilicon fuse 101, and then parts of the thermal oxide film 105 and the interlayer insulating film 106 made of SiO₂ or the like melt. Oxygen contained in the thermal oxide film 105 and the interlayer insulating film 106 thus melted reacts with molten polysilicon to produce oxide. However, since the oxide remains melted, it exhibits conductivity. Therefore, the current is still kept flowing.

Thereafter, at the time T₂ shown in FIG. 4A (6.0 μsec later after the start of voltage application in this figure), a voltage is sharply decreased to zero. Then, the flowing current also reaches zero, so that generation of Joule heat is stopped. This rapidly cools and solidifies the filament in the form of molten silicon oxide to produce an insulator of oxide. By electrically insulating the polysilicon fuse 101 in the manner described above, trimming of the semiconductor device can be carried out.

In the above-mentioned method for trimming a semiconductor device according to the second embodiment, polysilicon melted within the fusion portion 101a is formed into oxide by the reaction with oxygen contained in the interlayer insulating film 106 and the like. Thereafter, when an applied voltage is forcefully interrupted to reach zero, the filament is rapidly cooled and solidified into an insulator of oxide. Thus, the polysilicon fuse 101 is electrically insulated, and trimming of the semiconductor device is accomplished.

Unlike the conventional trimming method, it is unnecessary for the method for trimming a semiconductor device according to the second embodiment to split liquefied polysilicon by the influence of the film stress on the polysilicon fuse 101 placed by the sealing resin layer and the like. Therefore, the influence of the film stress placed on the polysilicon fuse 101 is reduced, so that a stable trimming of a semiconductor device can be carried out. This enables a stable writing even if sealing is made with a sealing resin having a large film stress on the polysilicon fuse 101.

Moreover, in the trimming method of the second embodiment, the period of time for which a voltage is applied is shorter than that of the conventional trimming method in which a voltage is applied for about 1 to 2 msec. This shortens the period of time for which Joule heat continues to be generated, so that damages to the semiconductor device caused by this heat can be reduced.

In the second embodiment, the voltage pulse is used which is forcefully interrupted 6.0 μsec later after the start of voltage application to reach 0 V. However, it is sufficient that the period of time until the interruption of a voltage is longer than the period of time required for a sufficient oxidation of the filament and a reliable writing, and as short as required to reduce damages to the semiconductor device caused by Joule heat.

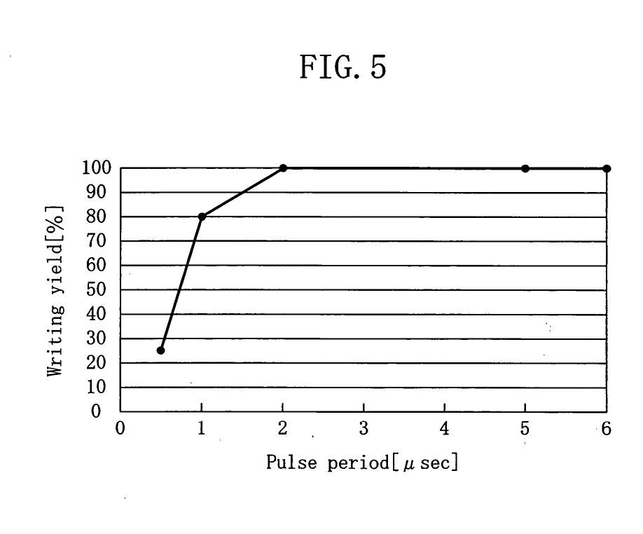

For the device fabricated by the method described above, the dependence of the writing yield thereof on the period of time until the interruption of a voltage (pulse period) was examined, and the result as shown in FIG. 5 was obtained. In this examination, a pulse period of 0.5 μsec produced a yield of about 25%, and a pulse period of 1.0 μsec produced a yield of about 80%. On the other hands, a pulse period of 2.0 μsec or longer produced a yield of about 100%. From this, it is recommendable to set the pulse period at 2.0 μsec or longer. A pulse period of 3.0 μsec or longer can attain a more reliable writing.

Moreover, in order to reduce damages of the heat, the pulse period is set at 100 μsec or shorter to provide an adequate effect, and the pulse period is set at 10 μsec or shorter to certainly provide an adequate effect.

In the second embodiment, the trimming method has been described in the case of using the semiconductor device with the polysilicon fuse according to the first embodiment. However, even if the trimming method of the second embodiment is employed not for that device but for the conventional semiconductor device with the polysilicon fuse, a stable writing and reduction of damages to the semiconductor device can be accomplished.

1. A semiconductor device comprising:
a polysilicon fuse with a fusion portion;
an interlayer insulating film formed to cover the polysilicon fuse and having a recess above the fusion portion;
a surface passivation film formed on the interlayer insulating film and having an opening on the recess;
a buffer film formed on the surface passivation film and filling the recess and the opening; and
a sealing resin layer formed on the buffer film,
wherein the buffer film releases film stress on the polysilicon fuse placed by the sealing resin layer.

2. A semiconductor device comprising:
a polysilicon fuse with a fusion portion;
an interlayer insulating film formed to cover the polysilicon fuse and having a recess above the fusion portion;
a buffer film formed on the interlayer insulating film and filling the recess; and
a sealing resin layer formed on the buffer film,
wherein the buffer film releases film stress on the polysilicon fuse placed by the sealing resin layer.

3. The device of claim 1,
wherein the buffer film is made of an organic insulating film.

4. The device of claim 3,
wherein the organic insulating film is a polyimide film.

5. A method for trimming a semiconductor device comprising a polysilicon fuse with a fusion portion,
wherein trimming is carried out by:
applying a voltage to the polysilicon fuse to melt the fusion portion; and
stopping, a predetermined time later after the start of the voltage application, the voltage application with a current flowing through the molten polysilicon fuse.

6. The method of claim 5,
wherein the predetermined time is from 3 to 100 μsec inclusive.

7. The method of claim 5,
wherein the predetermined time is from 3 to 10 μsec inclusive.

8. The method of claim 5,
wherein the semiconductor device comprises:
a polysilicon fuse formed above a semiconductor substrate and having a fusion portion;
an interlayer insulating film formed over the semiconductor substrate so that the interlayer insulating film covers the polysilicon fuse and having a recess above the fusion portion;
a buffer film formed on the interlayer insulating film and filling the recess; and
a sealing resin layer formed on the buffer film, and
the buffer film releases film stress on the polysilicon fuse placed by the sealing resin layer.
